(19) United States
(12) Patent Application Publication
(10) Pub. No.: US 2020/0321363 A1
(43) Pub. Date: Oct. 8, 2020

(54) PROCESS AND SYSTEM FOR MEASURING MORPHOLOGICAL CHARACTERISTICS OF FIBER LASER ANNEALED POLYCRYSTALLINE SILICON FILMS FOR FLAT PANEL DISPLAY

(71) Applicant: IPG PHOTONICS CORPORATION, Oxford, MA (US)

(72) Inventors: Florian HUBER, Shrewsbury, MA (US); Alexander LIMANOV, Millburn, NJ (US); Michael VON DADELSZEN, Merrimack, NH (US); Dan PERLOV, Sudbury, MA (US); Edward TSIDILKOVSKI, Chelmsford, MA (US); John HICKS, W. Brookfield, MA (US)

(21) Appl. No.: 16/301,248

(22) PCT Filed: May 8, 2017
(86) PCT No.: PCT/US2017/031574

§ 371 Date: Nov. 13, 2018

Related U.S. Application Data
(60) Provisional application No. 62/334,881, filed on May 11, 2016.

(51) Int. Cl. H01L 27/12; G01N 21/84; G01N 21/47; B23K 26/03; B23K 26/0622; B23K 26/064; B23K 26/06; B23K 26/08; B23K 26/082; B23K 26/53; H01L 21/02; H01L 21/66; H01L 21/67

(52) U.S. Cl. CPC H01L 27/1285; B23K 2101/40; G01N 21/4788; B23K 26/032; B23K 26/0622; B23K 26/064; B23K 26/0665; B23K 26/083; B23K 26/082; B23K 26/0821; B23K 26/53; H01L 21/02592; H01L 21/02532; H01L 21/02686; H01L 22/26; H01L 21/67115; H01L 21/67253; G01N 2201/105; G01N 2201/06113; G01N 2201/063; G01N 21/8422

(57) ABSTRACT

A method of measuring morphological characteristics of a laser annealed film having a crystalline structure, which is defined by at least one row of side-to-side positioned grains each having a length (Lg), which is uniform for the grains, and width (Wg), wherein a length of the row (Lr) corresponds to a cumulative width Wg of the grains and creates a diffraction of various orders of diffraction, the method includes generating a monochromatic light; training the monochromatic light onto a surface of the laser annealed film at an angle varying in a range between 0° (incident) and grazing angles; and measuring variations of properties of the monochromatic light diffracted from the surface, thereby measuring the morphological characteristics of the laser annealed film along the length (Lr) of the one row.

### BACKGROUND OF THE INVENTION

### Field of the Invention

This disclosure relates to the fabrication of flat panel displays. More particularly, the disclosure relates to a laser-based method and system for determining optical homogeneity of poly-silicon (p-Si) films on quartz substrate manufactured by a low-temperature polysilicon annealing (LTPS) method.

### Prior Art Discussion

The Flat Panel Display (FPD) fabrication environment is among the world's most competitive and technologically complex. The thin film transistor (TFT) technology is the basis for the FPD that can be either high-resolution, high-performance liquid crystal display (LCD), as shown in FIG. 1, or organic light emitting diode (OLED) which is of a particular interest here. The TFT display circuits are made on a thin semi-transparent layer of amorphous silicon (“a-silicon or a-Si”) and arranged in a backplane across the layer to correspond to respective pixels.

The industry realized that using poly-Si, which has the carrier mobility approximately two orders of magnitude greater than that of a-Si, substantially reduces the pixel size, improves the aperture ratio, and pixel resolution. As a result of these properties of poly-Si, portable/mobile electronic devices now feature high resolution flat panel displays.

There are two fundamentally different approaches for converting the a-Si into poly-Si through crystallization (annealing). One is a thermal annealing (TA) approach, and the other is a low-temperature poly-silicon annealing (LTPS) approach, which is part of the subject matter of this disclosure. In the latter, a-Si is initially thermally treated to convert into liquid amorphous Si, and then it is maintained in the molten state for a certain period of time. The temperature range sufficient to maintain the molten state is selected to allow the initially formed poly-crystallites to grow and crystallize. The LTPS approach is based on two generic methods—Excimer Laser Annealing (ELA) and sequential lateral solidification (SLS). The latter is the method used for producing p-Si films of this disclosure and is described in detail in co-owned U.S. application Ser. No. 14/790,170 incorporated here in its entirety.

The active matrix organic light emitting displays (AM OLED) are self-emissive devices outputting light by applying an electrical signal to colored organic or polymer material. Hence, OLED are current driven devices whereas the LCD technology is voltage driven. A uniform and stable threshold voltage (Vth) distribution of the thin film transistors (TFT) on the active matrix (AM) is essential for a good visual impression to the human eye. Therefore, the lifetime of an AM OLED is not only determined by the light emitting material but also by the reliability of the p-Si backplanes. The required high TFT Vth uniformity is thus a prerequisite for p-Si films with a higher degree of crystal homogeneity compared to a common LCD LTPS backplane.

The step of making p-Si films on glass is one of the earliest stages of the entire OLED FPD manufacturing process. Thus even if all later process stages are impeccably performed, inevitable yield losses will be due to excursions when this fundamental p-Si forming step shifts out of specification.

A need therefore exists for a method of quantitatively determining inhomogeneity of a p-Si film.

Another need exists for a system configured to implement the needed method.

### BRIEF DESCRIPTION OF THE DRAWINGS

The inventive method and system are illustrated by the following drawings, in which:

FIG. 1A is an image of laser annealed p-Si sample;

FIG. 1B is a low-resolution microscopy image of the sample;

FIG. 1C is a diagrammatic illustration of a two-row laser annealed p-Si sample with each row being defined by a plurality of grains;

FIG. 1D is a diagrammatic top view of individual grain;

FIG. 2 is the optical schematic of the inventive system;

FIG. 3 is a front view of the sample illustrating a scanning direction of used in the inventive schematic of FIG. 3;

FIG. 4 is an optical schematic of system for determining a diffraction angle used in the system of FIG. 2;

FIG. 5 is a raw image of one sample processed by the system of FIG. 2 with a 0.7 mm laser beam;

FIG. 6 is a scale illustrating the strength of the diffraction grating used in processing the sample of FIG. 5;

FIG. 7 is a raw image of another sample processed by the system of FIG. 2 with a 2 mm laser beam;

FIG. 8 is a scale illustrating the strength of the diffraction grating used in processing the sample of FIG. 7;

FIG. 9A is spatial grating strength distribution over several rows obtained with a 0.7 mm laser beam;

FIG. 9B is spatial grating strength distribution over a single row obtained with a 0.7 mm laser beam;

FIG. 10A is spatial grating strength distribution over several rows obtained with a 2 mm laser beam;

FIG. 10B is spatial grating strength distribution over a single row obtained with a 2 mm laser beam;

FIG. 11 is an orthogonal view of the disclosed laser annealing system.

### SPECIFIC DESCRIPTION

Reference will now be made in detail to the disclosed system. Wherever possible, same or similar reference numerals are used in the drawings and the description to refer to the same or like parts or steps. The word “couple” and similar terms do not necessarily denote direct and immediate connections, but also include connections through intermediate elements or devices. The drawings are in simplified form and are far from precise scale.

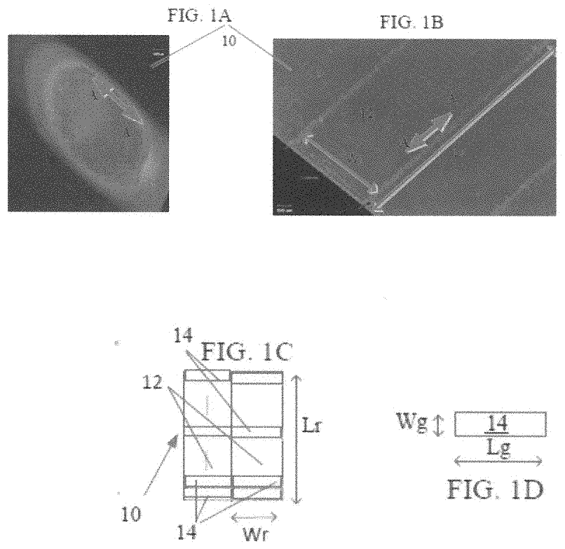

Referring to FIGS. 1A and 1B, laser-annealing of amorphous Silicon (a-Si) thin-films on SiO₂ substrate produces a poly-crystalline (p-Si) film 10. This film can be a used as a base material for production of OLED screens.

By illuminating film 10 with white light under a shallow angle and along the visible lines, a rainbow-like color pattern becomes visible. In particular, under moderate magnification (Leica Z16 APO, coaxial illumination) periodic lines perpendicular to the mm-wide stripes start to emerge (FIG. 1B). High magnification (Olympus BX51, transmission and DIC-mode) reveals bands of 0.7 μm spaced periodic lines, corresponding to the beam shift/step in re-melting process. This pattern suggests an underlying periodic structure in a direction A-A acting as a diffraction grating, the principle of operation of which is well known to one of ordinary skill in the optics.

The presence of the diffraction grating indicates that morphological characteristics, i.e., certain properties characterizing p-Si film 10 can be be measured. Based on these measurements, an acceptable range can be established and used in a mass-producing laser annealing apparatus to sort out ‘good panels”, i.e., panels characterized by the desired acceptable degree of optical inhomogeneity. The latter is critical to the uniformity of electrical mobility of charge carries and ultimately to the desired performance of FPD.

Referring specifically to FIG. 1B, the topography of the magnified image of p-Si film 10 includes multiple rows 12 abutting one another in the A-A direction, i.e., along a length Lr of the abutted side-by-side rows 12. As can be seen, each row 12 generally has a uniform rectangular cross-section with the width Wr of each row.

FIG. 1C is highly diagrammatic of film 10 shown to have two rows 12. The crystalline structure of p-Si is diagrammatically shown to have a plurality of grains 14 each with rather an ideal rectangular shape. In reality, the shape may differ from the shown shape. However, ideal or not, grains 14 each have a grain width Wg and length Lg both better seen in single grain 14 of FIG. 1D.

Such a detailed description of the disclosed row and grain geometries is very important for describing the periodic structure i.e., diffraction grating which defines length Lr of each row 12. Returning to FIG. 1C, the length Lr of row 12, thus, is a sum of widths Wg of respective grains 14. The length of grains Lg is uniform for all grains; it corresponds to the long axis of the annealing beam, used in the laser annealing system, and thus defines the width Wr of each row 12.

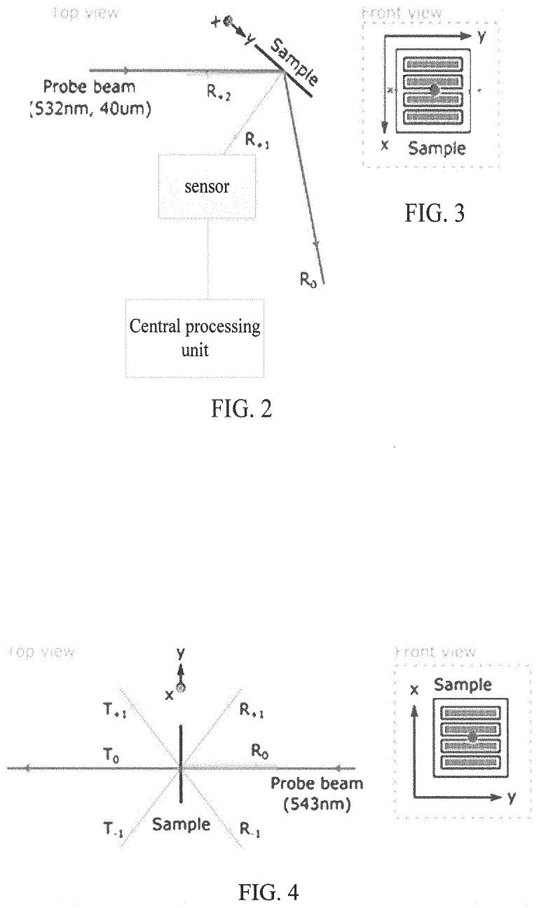

FIG. 2 illustrates the inventive system 20 configured to measure morphological characteristics of p-Si film 10. The latter is characterized by a crystalline structure defined by at least one row 12 of abutted long sides Lg of adjacent grains 14. The diffraction of various orders is created along the row length (Lr). The system 20 is capable of measuring the power of diffracted light indicative of the grating's strength.

The system 20 includes a laser source 22, which can be configured to operate in a continuous wave (CW), quasi-CW or pulsed regimes, outputs a monochromatic or very narrow-band light beam 24 at any desired wavelength, for example, 532 nm. Given only as an example, beam 24 has a 40 μm beam diameter. The beam 24 is focused onto the surface of sample 10 and has a footprint which is related to a desired spatial resolution of the measurement of variation of properties. The focused incident beam 24 impinges the ridges of the periodic structure, i.e. the diffraction grating, at an angle. The ridges are formed at the interface between adjacent grains of the same row. The diffracted beams are measured to determine respective intensities of any-order diffraction peak, for example first-order diffraction peak. In the experiments an angle of incidence is about 50°. In general, this angle may vary between 0° and grazing angle. Preferably the angle is selected so as to avoid artifacts caused by multiple reflections of the glass substrate.

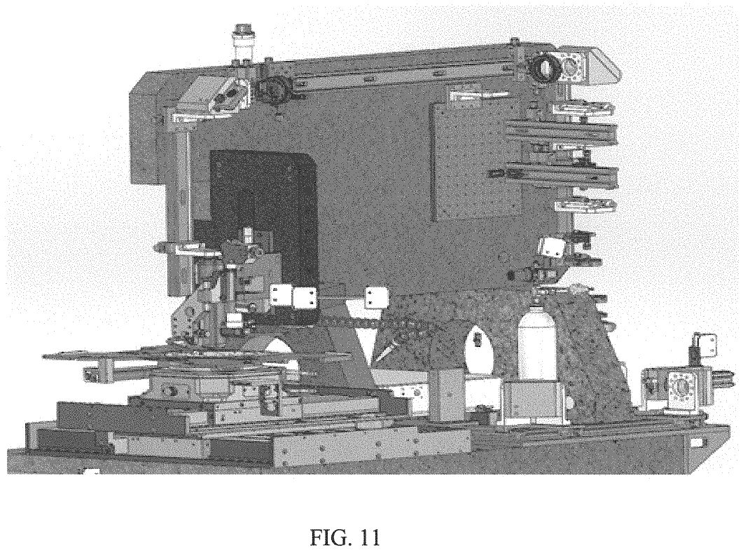

The photo-sensor 26 is used for measurement of the grating spatial strength and can be selected from a photodiode or CCD depending on the scanning scheme. The data based on measurements is collected in a central processing unit 28 where it is stored, processed and displayed to characterize the degree of optical inhomogeneity of film 10. This data then can be used to determine a range of acceptable parameters used in mass production by a laser annealing process as discussed herein in reference to FIG. 11.

The multiplicity of grains 14 defining the length Lr of row 12 is formed as a result of scanning the surface of sample 14 in the longitudinal direction Y of FIG. 3. In the tests, sample 10 is placed on a two dimensional translation stage supporting the laser annealed film. The stage displaces the sample relative to beam 24 which raster-scans the desired area of film 10 defined by illuminated rows 14. However, the raster-scanning may be performed by means of well-known techniques that allow the beam to be displaced relative to the sample or move both the sample and beam in opposite direction along the Y ordinate of FIG. 3. The known scanning techniques may include a galvanometer, scanning polygon, or acousto-optic deflector in conjunction with photodiode 26.

The desired area of the laser-annealed film can be imaged by a lens onto a pixel detector, such as CCD, at a desired diffraction order. Doing so generates a map of measured properties of the diffracted light which include a diffraction efficiency, diffraction angle corresponding to the number of illuminating arrays and polarization state of the diffracted light. The components necessary to measure the above-listed properties are well known to one of ordinary skill in the art.

The device and process steps performed by system 20 are used in numerous experiments and based on the measurement of the intensity of the diffracted light in the first-order diffraction peak. This is done at an angle of incidence of about 50° in order to avoid artifacts caused by multiple reflections of the glass substrate. To further reduce interference effects, the back surface of the samples is painted black with removable paint. The sample is then scanned in the sample plane.

The disclosed concept of course includes analyzing the periodic structure. In particular, as seen in FIG. 4, system 20 of FIG. 3 has been slightly modified for measurement of the angles θᵢ of the (±) first diffraction orders in reflection and transmission for normal incidence of a 543 nm laser beam. The spacing d of the grating relates to the diffraction as follows:

$$sin {θ}_{i} = \frac{i λ}{d}$$

The calculated grating spacing here is 0.70 μm, which is identical to the microscopically determined value.

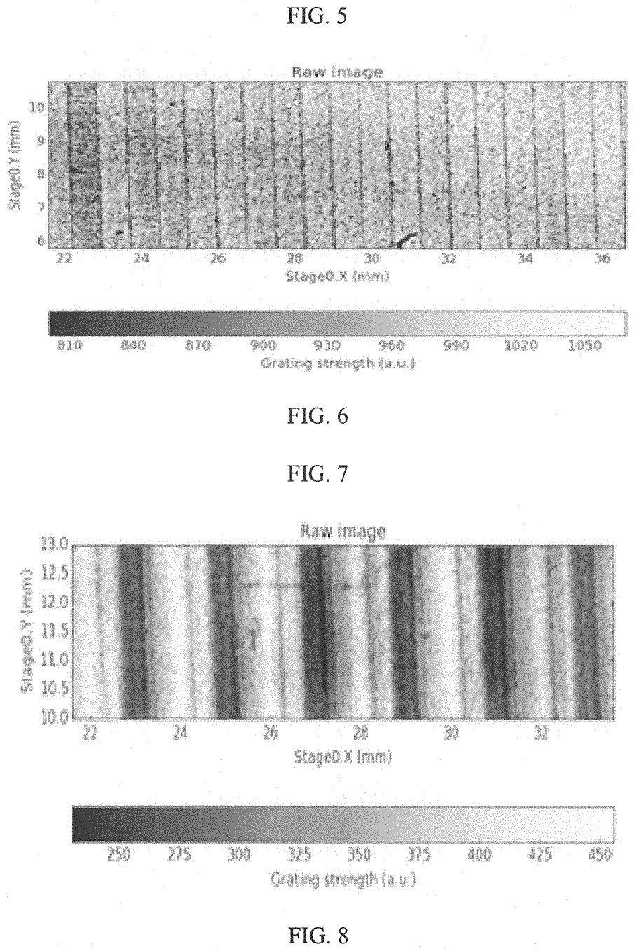

FIGS. 5 and 7 relate to post-processing the image by utilizing a high-pass filter with a spatial cut-off frequency of about 1 mm to reduce errors caused an imperfectly flat sample. In particular, FIGS. 5 and 7 show respective raw images of the two processed samples with 0.7 mm (FIG. 5) and 2 mm beam size (FIG. 7). The shown samples are accompanied by respective scales of FIGS. 6 and 8 representing respective grating scales.

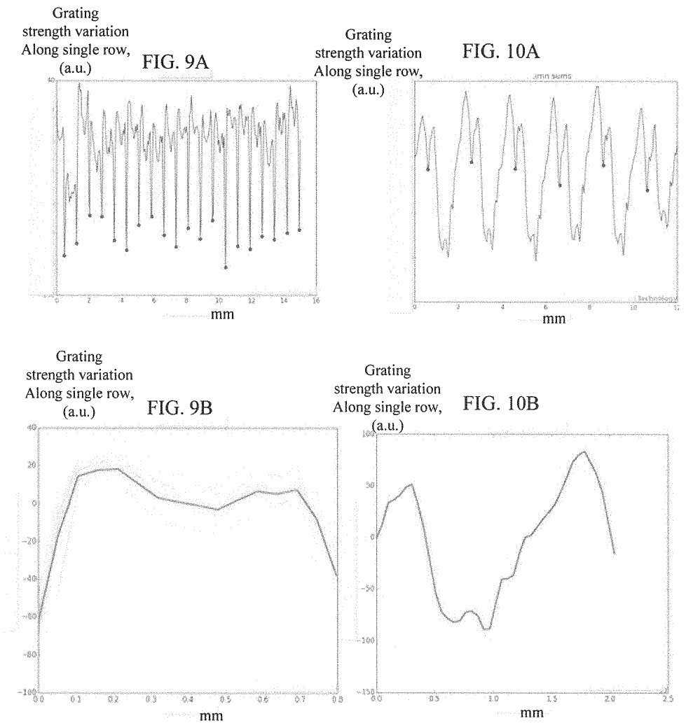

FIGS. 9A-9B and 10A-10B provide visualization of the spatial grating strength distributions of the samples shown on respective FIGS. 5 and 7. Referring specifically to FIG. 9A, the image of the sample of FIG. 5 corresponds to results obtained while scanning the desired area of the film which includes a multiplicity of rows 14 of FIG. 5 with a 0.7 mm laser beam. FIG. 9B shows the results based on raster-scanning of single row 14 with the same 0.7. mm beam. FIGS. 10A and 10B illustrate respective results of the multi-row scanned area and single row area with a 2 mm laser beam corresponding to the images on FIGS. 7 and 8. The above disclosed steps of disclosed processed samples of FIGS. 2, 7 and 9A through 10B are summarized in the following table illustrating quantitative measurements upon comparing the grating strengths of respective samples of FIGS. 5 and 7.

TABLE 1

| | Sample A | Sample B |
|---|---|---|
| Line width (mm) | 0.7 | 2.0 |
| Step size (um) | 0.7 | 0.7 |
| Diffraction angle (R₊₁) (°) | 50.9 | 50.4 |
| RMS diffraction (a.u.) | 951 | 347 |
| Line average p-p (a.u) | 80 | 198 |
| Line average std. dev. (a.u.) | 20 | 52 |

Where p-p is peak to peak and a.u—arbitrary units.

Referring now to FIG. 11, the above disclosed method and system may function as a stand-alone device for determining morphological characteristics of p-Si films annealed by laser annealing system 50, which is disclosed in detail in U.S. Patent Application No. 62/315,310. Alternatively, system 20 and its modifications maybe incorporated in system 50. The latter includes a laser source (not shown) outputting a pulsed beam. The beam is guided along a beam path through several optical units some of them are briefly disclosed. First, the beam is guided through a collimating unit operative to sequentially collimate the pulsed light beam along short and long axes thereof. Thereafter the collimated beam is homogenized in a unit operative to provide the uniform linear beam directed and focused at a mask plane which is immediately before the mask. The film of a-Si to be converted into a p-Si is placed on a stage providing relative displacement between the beam and film.

Returning to inventive system 20, it may be position so as to provide coupling of the laser beam 24 (FIG. 3) to the ablated/crystalized part of amorphous opposing the film. This scheme allows detecting certain properties of already crystallized part that are not within the established specification or range. If a small portion of the entire film is determined to have the properties which are out of the specification, it is possible to provide a feedback to annealing system's components and adjust the “bad” properties basically in real time. Such an approach would allow the rest of the “good” film to be further used in the process of manufacturing FPD. If, however, a larger portion of the entire film is determined to be unsatisfactory, this film can be discarded in its entirety preventing thus losses which would otherwise be incurred regardless of how well the rest of the FPD manufacturing goes. Alternatively, it is known that system 50 is typically adjusted on a regular basis. In this case the calibrating sample processed by system 20 is used to adjust the parameters of system 50.

In summary, optical inhomogeneity can be potentially minimized by reducing the peak-to-peak variation between adjacent grains 14, and/or possibly by breaking the periodicity of the structure by randomizing the step size.

Having described at least one of the preferred embodiments of the present disclosure with reference to the accompanying drawings, it is to be understood that the disclosure is not limited to those precise embodiments, and that various changes, modifications, and adaptations may be effected therein by one skilled in the art without departing from the scope or spirit of the disclosure as defined in the appended claims.

1. A method of measuring morphological characteristics of a laser annealed film having a crystalline structure, which is defined by at least one row of side-to-side positioned grains each with a length (Lg), which is uniform for the grains and defines a width of the one row (Wr), and width (Wg), wherein a length of the row (Lr) corresponds to a cumulative width Wg of the grains and creates a diffraction having various orders, the method comprising:
generating a monochromatic light;
training the monochromatic light onto a surface of the laser annealed film at an angle varying in a range between 0° (incident) and grazing angles; and
measuring variations of properties of the monochromatic light diffracted from the surface, thereby measuring the morphological characteristics of the laser annealed film along the length (Lr) of the one row.

2. The method of claim 1, wherein the film is a polysilicon (p-Si) film and has an array of one and additional adjoined rows cumulatively defining a desired area of the laser annealed film.

3. The method of claim 2 further comprising raster-scanning the desired area of the laser annealed film with the trained monochromatic light having a footprint which is related to a desired spatial resolution of the measurement of variation of properties.

4. The method of claim 2 further comprising illuminating the desired area of the laser-annealed film to be imaged onto a pixel detector at a desired diffraction order, thereby measuring the variations.

5. The method of claim 4, wherein illuminating the desired area includes imaging of the diffracted order of the trained monochromatic light.

6. The method of claim 1 further comprising generating a map of measured properties of the diffracted light, wherein the properties include a diffraction efficiency, diffraction angle corresponding to a number of illuminating arrays and polarization state of the diffracted light.

7. The method of claim 6 further comprising determining a tolerance range of the measured properties of the diffracted light.

8. The method of claim 7 further comprising determining a distributed inhomogeneity (MURA) of a plurality of the laser annealed rows.

9. The method of claim 7 further comprising:
comparing the measured properties of the laser annealed film during a laser annealing process with the tolerance range, and
generating a control signal interrupting the laser annealing process if any of the measured properties of the diffracted light is outside the tolerance range.

10. The method of claim 8 further comprising:
comparing the measured properties with the tolerance range during a laser annealing process of a part of an amorphous silicon film that has been converted to the p-Si film, while the rest of the film is being annealed, and
generating a control signal in real time if any of the measured properties is outside the tolerance range, and
adjusting parameters of the laser annealing process to bring the properties within the range.

11. A system for measuring morphological characteristics of a laser annealed film having a crystalline structure, which is defined by at least one row of side-to-side positioned grains each having a length (Lg), which is uniform for the grains and defines a width of the one row (Wr), wherein a length of the row (Lr) corresponds to a cumulative width Wg of the grains and defines a diffraction of various orders of diffraction, the system comprising:
a laser source of monochromatic light;
a guiding optics training the monochromatic light onto a surface of the laser annealed film at an angle;
a sensor configured to measure variations of properties of the diffracted monochromatic light and generate a signal; and
a processing unit receiving the signal from the sensor and operative to determine the inhomogeneity of grains along the one row.

12. The system of claim 11, wherein the laser source is operative to laser-anneal the film so as to provide an array of adjoined rows thereon which cumulatively define a desired area, the rows each having the width Wr and the length of the row Lr.

13. The system of claim 11 further comprising a scanner operative to raster-scan the desired area of the laser annealed film with the trained monochromatic light having a footprint which is related to a desired spatial resolution of the measurement of variation of properties.

14. The system of claim 13, wherein the scanner includes a galvanometer, scanning polygon, or acousto-optic deflector, the sensor being a photodiode.

15. The system of claim 11, wherein the a scanner includes an imaging system, the imaging system being configured with the sensor, including a pixel detector which is spaced from the laser annealed film, and an imaging lens between the desired area, which is illuminated by the monochromatic light, and a lens imaging the illuminated desired area on the pixel detector, wherein the pixel detector is a charge-coupled device (CCD).

16. The system of claim 11, wherein the measured properties of the diffracted light include the measured inhomogeneity of diffraction efficiency, diffraction angle (number of illuminating arrays) and polarization state of the diffracted light.

17. The system of claim 11, wherein the processing unit is operative to determine a tolerance range of the measured inhomogeneity of the properties of the diffracted light.

18. A laser annealing system for annealing an amorphous silicon (a-Si) film on a glass substrate, comprising:
a support underlying the a-Si film;
a fiber laser source outputting a pulsed light beam;
a collimating unit operative to sequentially collimate the pulsed light beam along short and long axes thereof;
a homogenizing unit operative to process the collimated laser beam so as to provide a uniform linear pulsed beam trained at a mask plane;
a focusing unit operative to focus the uniform linear beam at the mask plane opposing the film;
an actuator operative to provide displacement of the support with the p-Si film and the uniform linear beam relative to one another so that to convert the a-Si film into a film of a polycrystalline silicon (p-Si) crystalline structure, which is defined by at least one row of side-to-side positioned grains each having a length (Lg), which is uniform for the grains, and width (Wg), wherein a length of the row (Lr) corresponds to a cumulative width Wg of the grains and defines a diffraction of various orders of diffraction; and
the system operative to quantitatively determine inhomogeneity of the p-Si film as recited in claims 11-17.
